(19) United States
(12) Patent Application Publication
(10) Pub. No.: US 2026/0126601 A1
(43) Pub. Date: May 7, 2026

(54) OPTICAL LINK WITH REDUNDANT LIGHT SOURCE AND METHOD OF COUPLING

(71) Applicant: HYPERLUME INC., Ottawa (CA)

(72) Inventors: Mohsen Asad, Ottawa (CA); Hossein Fariborzi, Auburndale, MA (US); Bilal Janjua, Toronto (CA)

(73) Assignee: HYPERLUME INC., Ottawa (CA)

(21) Appl. No.: 19/060,702

(22) Filed: Feb. 23, 2025

Related U.S. Application Data
(63) Continuation of application No. PCT/CA2024/051452, filed on Nov. 1, 2024.

(51) Int. Cl. G02B 6/42; H10H 29/851

(52) U.S. Cl. CPC G02B 6/4215; G02B 6/4212; H10H 29/8512

(57) ABSTRACT

An optical interconnect system comprising: a primary substrate; one or more light sources for emitting light fabricated on the primary substrate; at least one communication medium for transmitting the light, wherein the at least one communication medium is separated from the one or more light sources by a predefined distance; the at least one communication medium comprising a numerical aperture, and wherein the numerical aperture, the one or more light sources, and the at least one communication medium, are dimensioned to minimize loss of optical power coupling of the emitted light into the at least one communication medium; and wherein the predefined distance is selected such that the emitted light is coupled into the at least one communication medium without an optical component.

### FIELD

Aspects of the disclosure relate to communication methods and systems.

### BACKGROUND

Enabling large-scale applications like artificial intelligence (AI) and machine learning demands rapid processing of vast amounts of data, predominantly within data centers. To enhance computational speed, optimization of communication between processors and memories is imperative. However, traditional copper interconnects suffer from latency issues and cannot provide the desired bandwidth at low power consumption. Moreover, they generate significant heat, necessitating efficient cooling systems.

Optical interconnect may replace copper interconnect providing higher bandwidth at lower latency. Light sources such as micron-size light-emitting diodes (micro-LEDs), vertical-cavity surface-emitting lasers (VCSELs), or other lasers may be used for shorter-range communication such as chip-to-chip communication. Micro-LEDs are reliable light sources that operate at high temperatures with low failure rates.

Optical light sources such as lasers and LEDs are used for generating photons and sending information to optical waveguides such as fiber optics. The lifetime of the light source may degrade over time due to thermal and electrical stresses resulting in system operation failure.

### SUMMARY

In one of its aspects, an optical interconnect system comprising:
a primary substrate;
one or more light sources for emitting light fabricated on the primary substrate;
at least one communication medium for transmitting the light, wherein the at least one communication medium is separated from the one or more light sources by a predefined distance;
the at least one communication medium comprising a numerical aperture, and wherein the numerical aperture, the one or more light sources, and the at least one communication medium, are dimensioned to minimize loss of optical power coupling of the emitted light into the at least one communication medium; and
wherein the predefined distance is selected such that the emitted light is coupled into the at least one communication medium without an optical component.

In another aspect, an optical interconnect system comprising:
a primary substrate;
one or more light sources for emitting light fabricated on the primary substrate;
at least one communication medium for transmitting the light, wherein the at least one communication medium is separated from the one or more light sources by a predefined distance, and wherein the at least one communication medium comprises a numerical aperture;
an optical component configured to collimate the emitted light for coupling into the at least one communication medium; and
wherein the numerical aperture, the one or more light sources, and the at least one communication medium, the predefined distance, and optical component are dimensioned to minimize loss of optical power coupling of the emitted light into the at least one communication medium.

In another of its aspects, a method for assembling an optical interconnect system, the method comprising the steps of:
providing at least one light source for emitting light,
providing at least one communication medium for transmitting the light, wherein the at least one communication medium is separated from the one or more light sources by a predefined distance, and wherein the at least one communication medium comprises a numerical aperture;
providing an optical component configured to collimate the emitted light for coupling into the at least one communication medium; and
wherein the numerical aperture, the one or more light sources, and the at least one communication medium, the predefined distance, and optical component are dimensioned to minimize loss of optical power coupling of the emitted light into the at least one communication medium.

The methods and systems described herein use high NA glass and plastic fibers or high NA imaging fiber bundles and associated optical and mechanical components and configurations to enable optimized light collection. Since short-distance connection is the main goal of these optical cables, the propagation loss and dispersion are less critical for the guiding fiber, and fiber larger diameter fibers and/or high NA fibers may be employed. Based on the size of the micro-LED source and the divergence angle, an optical fiber with a diameter large enough and high enough NA is used in the apparatus to maintain the low loss optical power coupling into the fiber. Employing high NA fibers allows higher optical misalignment errors in the system, enabling passive alignment of the components in the production line and thereby reducing the costs and scalability of the design. By optimizing the fiber diameter and NA, the etendue of the micro-LED source can be maximally preserved. The apparatus employs high NA fibers and/or imaging fibers along with end-coupling to maximize the coupling of micro-LED sources, which is not as directional as laser sources. The short-distance link required for chip-to-chip or board-to-board communication minimizes the impact of the optical dispersion, allowing for large-diameter fibers to be used for light delivery in higher bandwidth conditions. The low coupling loss in an LED-based visible communication link is the key to the low-power and high data rate chip-to-chip communication link.

One approach may be to use redundant optical light sources coupled to a shared waveguide. If one light source fails, it may be detected by missing the signal on the other side and the redundant light source starts operation. This increases the resiliency and lifetime of the optical link for longer operation.

In addition, most of the optical links are designed and fabricated for a specific bandwidth. The technology used for transistors, active and passive optical elements are designed to meet the bandwidth requirements. If a higher bandwidth is required, the optical elements and driver should be upgraded while the channel (such as fiber optics) remains intact. If a redundant light source may be integrated into an optical waveguide and driven independently, a programmable optical bandwidth may be achieved. If a higher bandwidth is required, an additional light source may be activated or programmed while the communication channel is fixed.

If the redundant light source is driven independently at the linear regime (such as changing the intensity and not turning it on and off), an extra level of optical intensity may be achieved in the communication. If there is only one light source, changing the intensity may only generate two levels of light intensity. However, 2 light sources may be coupled to an optical channel and be driven independently, 4 levels of light intensity will be obtainable. The same trend is consistent for 3 light sources and 2³ (8) light levels are achievable. As a result, by having n number of light sources, 2ⁿ level of light intensity may be generated that increases the communication capacity of an optical channel.

While individual light sources may drive limited bandwidth, a massive array of parallel light sources may be employed. Redundancy in optical light sources per communication channel may increase the bandwidth and reliability of the transceivers. The redundant light sources may be coupled to the same waveguide, and it may replace a failed emitter. Furthermore, the redundant light sources may be driven independently to increase the data transfer bandwidth. All the light emitters may be coupled to a single waveguide such as fiber optics or polymer which results in a higher bandwidth per channel. One potential method to integrate different light sources is to use various materials with various emission wavelengths or to employ down-conversion or up-conversion mechanisms on the light sources.

The redundant light sources may be fabricated on a single chip with common contact or they may be individual dies integrated on a single carrier/substrate. Integrating waveguides on light sources may be done using active or passive alignment. An array of micro-lens may be used to reduce the crosstalk between the channels or collimate the light emitted from sources. As a result, light source and waveguide coupling may be optimized simultaneously.

### BRIEF DESCRIPTION OF THE DRAWINGS

Several exemplary embodiments of the present disclosure will now be described, by way of example only, with reference to the appended drawings in which:

FIG. 1 illustrates an optical communication link including a driver, a light source, and an optical waveguide;

FIG. 2 illustrates an optical communication link with redundant light sources;

FIG. 3 illustrates an optical communication link with various light sources with different emission wavelengths coupled into an optical waveguide;

FIG. 4 illustrates an optical communication link which a lens is used to enhance light coupling of various light sources to an optical waveguide;

FIG. 5 illustrates an optical communication link that a lens is used to enhance light coupling of redundant light sources to an optical waveguide;

FIG. 6 illustrates an optical communication link with various light sources with independent lenses on each light source;

FIG. 7 illustrates an optical communication link with redundant light sources with independent lenses on each light source;

FIG. 8 illustrates an optical communication link with redundant light sources and a space between light sources;

FIG. 9 illustrates an optical communication link with a lens array integrated on top of light sources;

FIG. 10 illustrates an optical communication link with a lens array integrated on top of light sources with individual light paths;

FIG. 11 illustrates an optical communication link with light sources integrated into a fabric and the fabric is connected to the driver;

FIG. 12 illustrates an epitaxial structure grown on a growth substrate;

FIG. 13 illustrates the epitaxial structure after patterning and partial removal by etching to create redundant light source;

FIG. 14 illustrates the epitaxial structure after removing part of it and exposing the growth substrate;

FIG. 15 illustrates the epitaxial structure with a contact created on part of the epitaxial structure;

FIG. 16 illustrates the patterned epitaxial structure with contact created on part of the structure;

FIG. 17 illustrates the patterned epitaxial structure with contact created at the same height;

FIG. 18 illustrates the patterned epitaxial structure coated with a passivation layer;

FIG. 19 illustrates the patterned structure with openings in the passivation layer;

FIG. 20 illustrates the patterned structure with contact created on top and at the same height.

FIG. 21 illustrates the fabricated redundant light sources when the common pad at the center is deposited on the side devices to be at the same height;

FIG. 22 illustrates the alignment of redundant light sources with the pads on a CMOS driver substrate;

FIG. 23 illustrates the integrated packaged light sources onto pads on a CMOS driver substrate;

FIG. 24 illustrates the integrated redundant micro-LEDs on a CMOS substrate when an adhesive is used for hybrid bonding;

FIG. 25 illustrates the process of removing the growth substrate from redundant micro-LEDs;

FIG. 26 illustrates the fabricated redundant micro-LEDs in various sizes;

FIG. 27 illustrates the fabricated redundant micro-LEDs in an array format;

FIG. 28 illustrates the measurement results of the extra information level that has been transmitted using redundant micro-LEDs emitter;

### DESCRIPTION

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Moreover, it should be appreciated that the particular implementations shown and described herein are illustrative of the invention and are not intended to otherwise limit the scope of the present invention in any way. Indeed, for the sake of brevity, certain sub-components of the individual operating components, conventional data networking, application development and other functional aspects of the systems may not be described in detail herein. Furthermore, the connecting lines shown in the various figures contained herein are intended to represent exemplary functional relationships and/or physical couplings between the various elements. It should be noted that many alternative or additional functional relationships or physical connections may be present in a practical system.

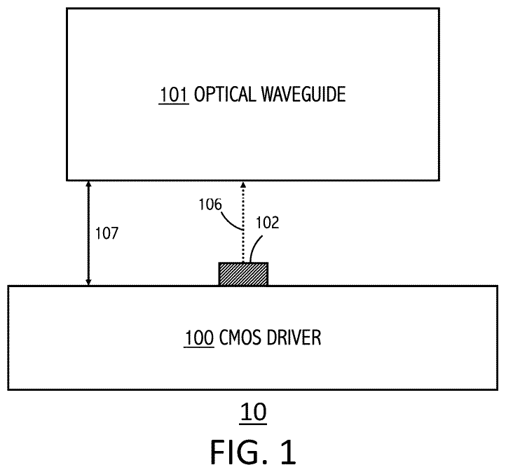

FIG. 1 depicts an optical communication link 10 in which a light source such as micro-LED (102) is integrated on a CMOS driver substrate (100). The emitted photons (106) are guided towards a communication medium (101). In one example, the communication medium (101) may be an optical fiber, optical waveguide, or any other guiding medium comprising air, an organic material or an inorganic material. A distance (107) between the optical waveguide (101) and micro-LED (102) is controllable such that for a desired numerical aperture (NA) of the optical waveguide (101) the emitted light or photons (106) may be coupled to the waveguide without requiring any optical components.

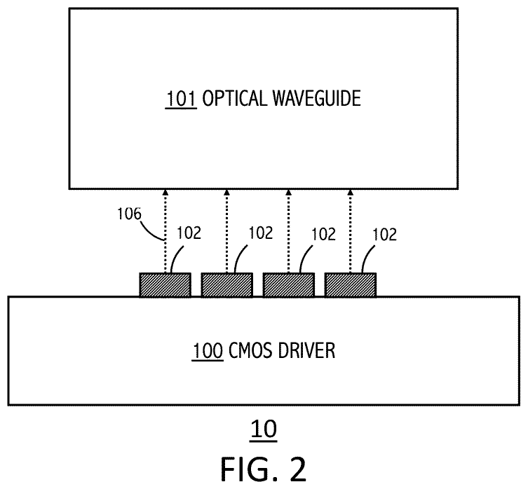

FIG. 2 illustrates an optical communication link (10) with a plurality of light sources (102a-d), in which one or more of the light sources (102) are redundant. The light sources (102) may be identical and emit light of the same wavelength, and the emitted photons (106) may be all coupled into the optical waveguide (101). As such, a redundant light source (102), or a set of the redundant light sources (102) may be activated if any of the light sources (102) are inoperative. In one example, a power measurement procedure may be employed to measure the received power on the receiver side and if the power drops from a certain value, the redundant light source (102) may be enabled. In another method, all the light sources (102) may be tested using an optical metrology machine or tool before final packaging. If a light source (102) is not fully functional e.g., dim or not turning on, the redundant light source (102) may be activated, until all the light sources (102) are functioning according to their specifications. Also, multiple light sources (102) may be activated at the same time with different intensities to increase the information transmission capacity.

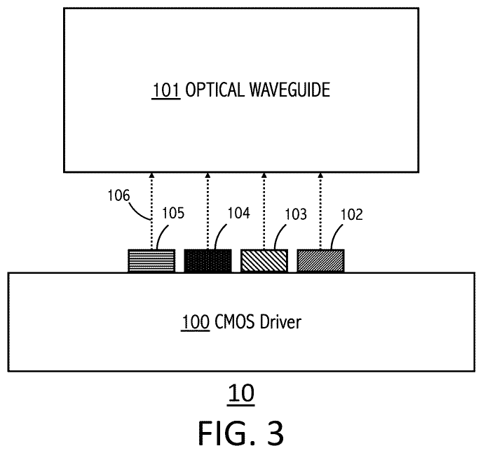

FIG. 3 illustrates an optical communication link (10) with various light sources of (102), (103), (104), and (105) which are emitting different wavelengths. The individual light sources (102), (103), (104), and (105) may be, but not limited to, micro-LEDs with different emission wavelengths in the visible spectrum. The emission wavelength spacing may be more than the full-width half-maximum of individual light sources (102), (103), (104), and (105) to prevent data mixing. The light sources (102), (103), (104), and (105) may be packaged on the substrate (100) individually from different processed wafers or they can be from the same wafer source. In one example, a colour conversion layer may be assembled on top of the light sources (102), (103), (104), and (105) to generate various wavelengths. In one example, a wavelength multiplexing modulation method may be implemented to employ various light sources, such as various micro-LEDs. By designing selective photodetectors on the receiver side, the complex signal processing may be eliminated. As shown in FIG. 3, the emitted photons (106) from the light sources (102), (103), (104), and (105) may be coupled to the waveguide (101) without using an optical component system, such as a lens, lens system, or extra light guiding medium.

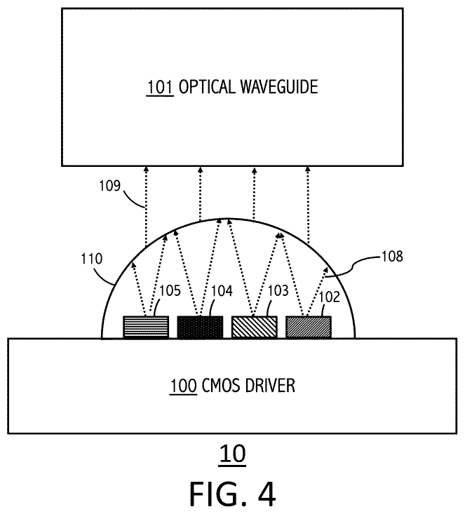

FIG. 4 illustrates an optical communication link (10) with various light sources of (102), (103), (104), and (105), and comprising an optical component system, such as a lens, lens system (110) fabricated over the light sources (102), (103), (104), (105). The lens (110) may be designed and fabricated in a way that may collimate the emitted photons (108) and collimated photons (109) may be coupled to the waveguide (101). In one example, the lens (110) may be made in micron-scale and comprises glass, polymer or any other type of materials. The lens (110) structure may comprise a dome-shape, among other shapes, or structural lens and any other type of lenses may be used. In one example, the design of the lens (110) may be optimized for a single wavelength or for a wide range of spectrum.

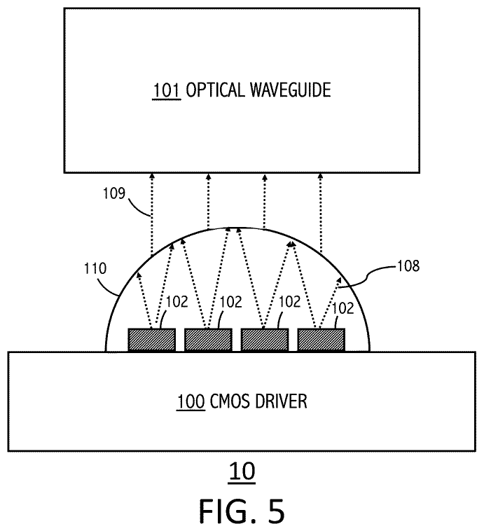

FIG. 5 illustrates an optical communication link (10) with various light sources (102) and comprising an optical component system, such as a lens, lens system (110) fabricated on the light sources (102). All the light sources (102) may be in a single wavelength or similar distribution of wavelength, and the micro-lens (110) may help in light extraction from light sources. The collimated photons (109) may be coupled to a waveguide (101). The micro-lens (110) might be fabricated over the light sources (102) using polymers and optical processing or the micro-lens (110) may be made on a separate substrate such as glass and may be assembled on top of light sources (102).

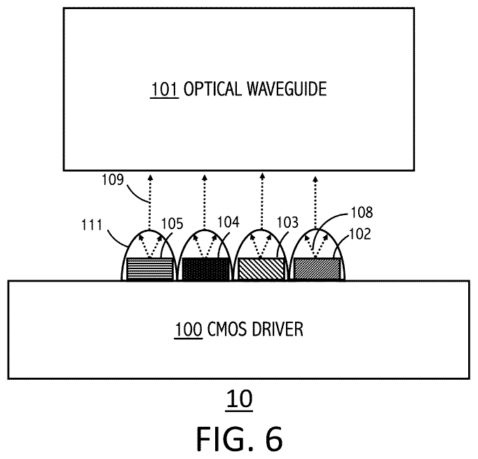

FIG. 6 illustrates an optical communication link (10) with various light sources (102), (103), (104), (105) and comprising an optical component system, such as a lens, lens system or micro-lenses (111) fabricated/mounted on top of individual light sources (102), (103), (104), (105). The extracted photons (109) may be collimated for enhancing the coupling to waveguide (101). The individual lens (111) may be optimized for individual wavelength emitted from the light sources (102), (103), (104), (105).

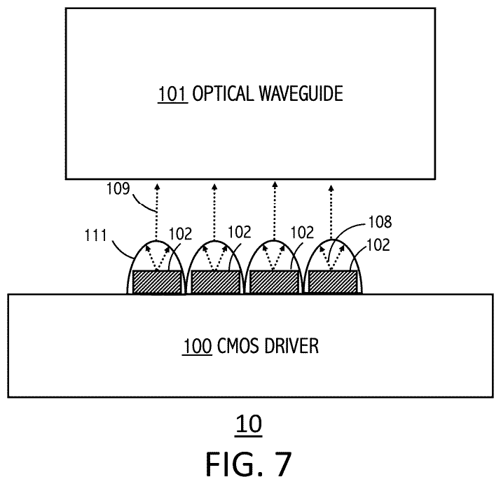

FIG. 7 illustrates an optical communication link (10) with various light sources (102) and comprising an individual optical component system (111), such as a lens, lens system fabricated on an individual light source (102). The size of the lens (111) on individual light sources (102) may be smaller than the lens (110) which may be fabricated on all light sources (102). As a result, higher level of collimation might be achieved. In addition, if one of the lenses (111) does not perform reliably, there is a redundancy in both the light source (102) and the lens (111).

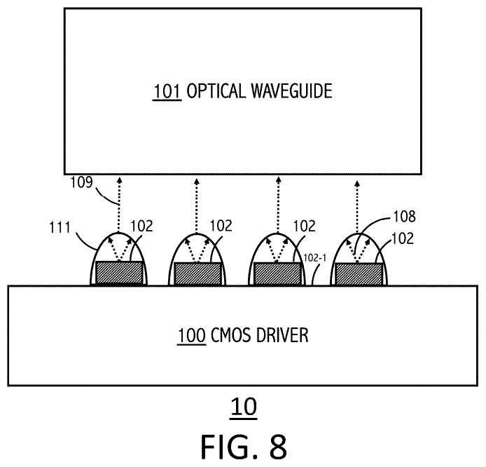

FIG. 8 illustrates an optical communication link (10) with various light sources (102) and comprising an individual optical component system (111), such as a lens, lens system fabricated on an individual light source (102). The sources (102) with micro-lenses (111) may be separated from each other by a space or distance (102-1) to minimize the crosstalk between the light sources (102). The space (102-1) may be created for alignment process, reducing crosstalk or ease of micro-lens fabrication.

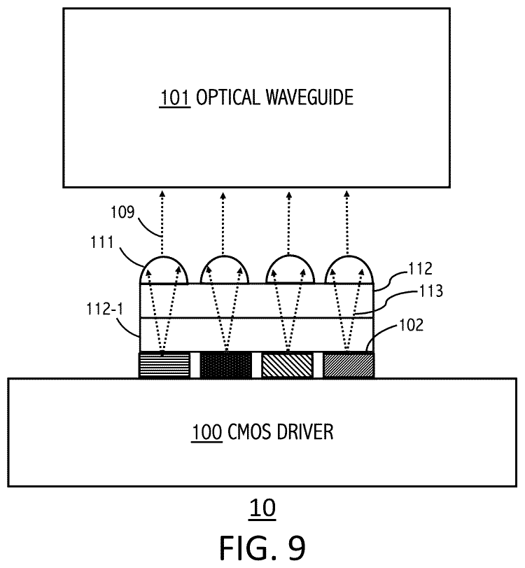

FIG. 9 illustrates an optical communication link (10) with light coupled to a waveguide (101) using lenses (111) integrated on top of individual light sources (102). Micro-lenses (111) might be fabricated on a transparent substrate (112) such as glass and an adhesive layer (112-1) might be used to integrate the micro-lens array to the light sources (102). The micro-lens (111) might be fabricated using different technique or material on a transparent substrate (112). The emitted photons (113) from light source may be collimated (109) after passing the micro-lens (111).

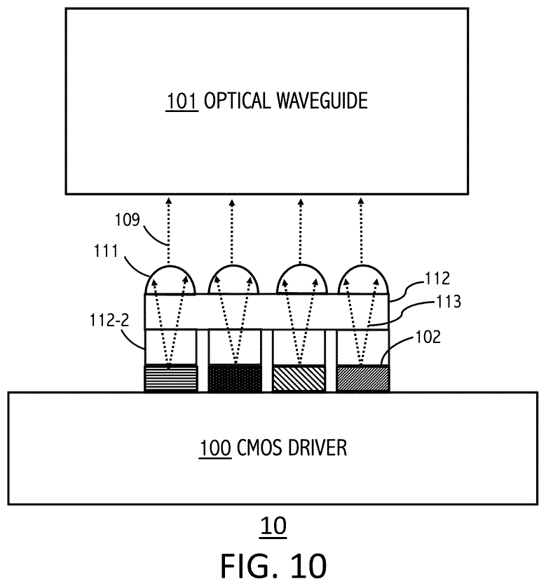

FIG. 10 illustrates an optical communication link (10) with various light sources (102) and comprising an individual optical component system (111), such as a lens, lens system, with a light path or waveguide (112-2) to connect the light sources (102) to a micro-lens array substrate (112). The light path (112-2) may comprise photo-definable polymers with required refractive index which may be an optical communication link (10) with a lens array (111) integrated on top of the light sources (102). The sidewall of the light path (112-2) may be covered with a reflective material to keep the light within the waveguide (112-2). The refractive index of the light path material might be chosen in a way that may help light extraction.

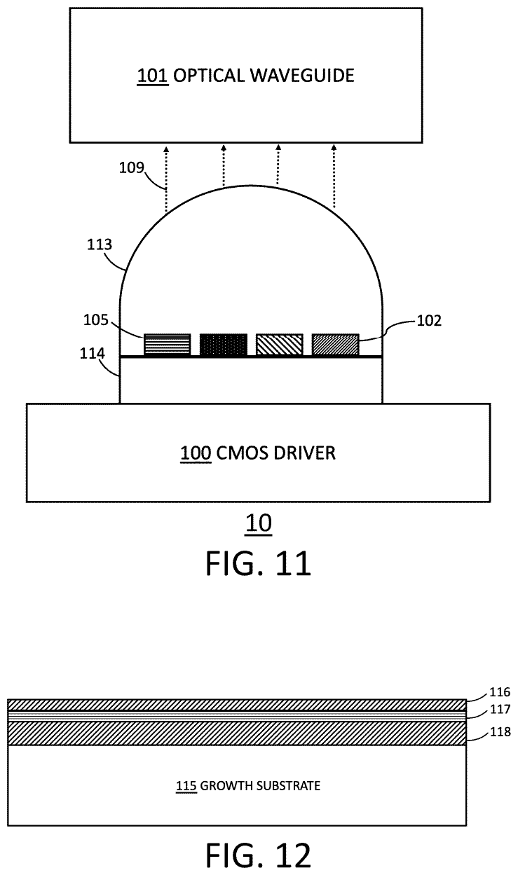

FIG. 11 illustrates an optical communication link (10) with various light sources (102, 105) and comprising an optical component system (113), such as a lens, lens system structure, in which the light sources (102), (105) are build or transferred on a secondary substrate (114). The secondary substrate (114) might be connected to the CMOS Driver (100) through conductive vias. The lens (113) may be fabricated on top of light sources (102, 105) to guide the photons (109) towards the optical waveguide (101).

FIG. 12 illustrates the epitaxial structure that may be used to fabricate light sources (102). The growth substrate (115) may comprise silicon, sapphire, GaN, GaAs or any other material. The epitaxial structure may comprise n-type material (118), quantum well (117) or p-type semiconductor (116). The location of n-type and p-type may be changed, for example (118) might be p-doped material and (116) might be n-doped material. The layer (117) may be quantum wells or quantum dots that may emit the photons. The layers (116) and (118) may comprise a multi-layer structure to provide both optical and electrical structure.

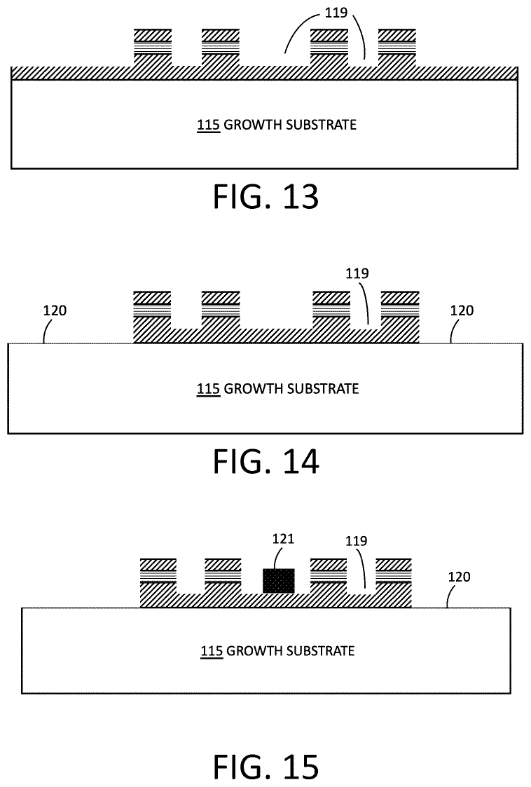

FIG. 13 illustrates the epitaxial layers after patterning, with part of the epitaxial layer removed (119) using physical or chemical processes.

FIG. 14 illustrates the substrate after removing the epitaxial layer and exposing the growth substrate (115) in some areas (120).

FIG. 15 illustrates the structure when a contact (121) is formed on top of epitaxial structure on the area (119). This contact (112) may comprise a multi metal layer to form ohmic to an epi layer and to provide other functionality for next step processing.

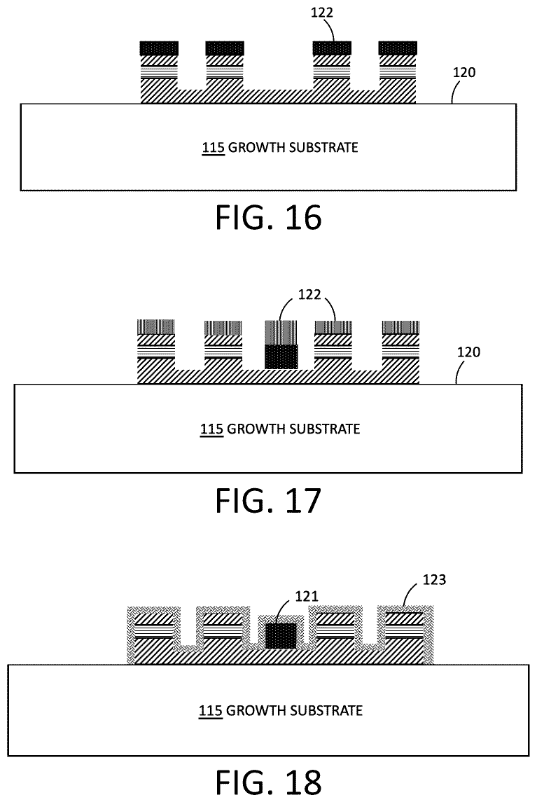

FIG. 16 illustrates the epitaxial structure after forming a contact (122) on layer (118). This layer (118) may be formed on an epi structure before or after forming the layer (121) or before patterning the epitaxial structure.

FIG. 17 illustrates the structure when the layer (122) is formed on top of epitaxial structure and the contact (121) and provide a same height. The layer (122) may comprise multi metal layers.

FIG. 18 illustrates the structure when a passivation layer (123) covers the topside and sidewall of the patterned epitaxial structure. The passivation layer (123) may comprise dielectrics or polymer and may comprise different materials to provide both insulating and optical properties.

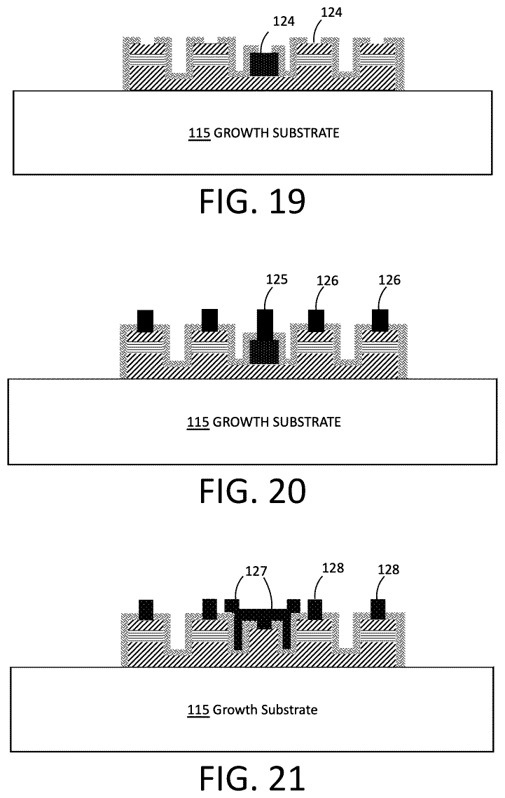

FIG. 19 illustrates the structure when the passivation layer (123) is patterned and vias are open at area (124) on top of contacts and pads.

FIG. 20 illustrates the structure after forming the pads (125) and (126) on top of devices. (125) and (126) might be at the same height and might be fabricated in a single step or double step. If a double-step fabrication is used, the pads with on either anode or cathode may be fabricated first. The pads (125) and (126) may comprise hard materials such as copper or gold and might be finished with a solder such as Sn.

FIG. 21 illustrates the structure when the pad (127) is formed to overlap the device structure on the highest height to enable planarization between (127) and (128). In this case the (127) and (128) may be made in a single step and extra processing may not be required.

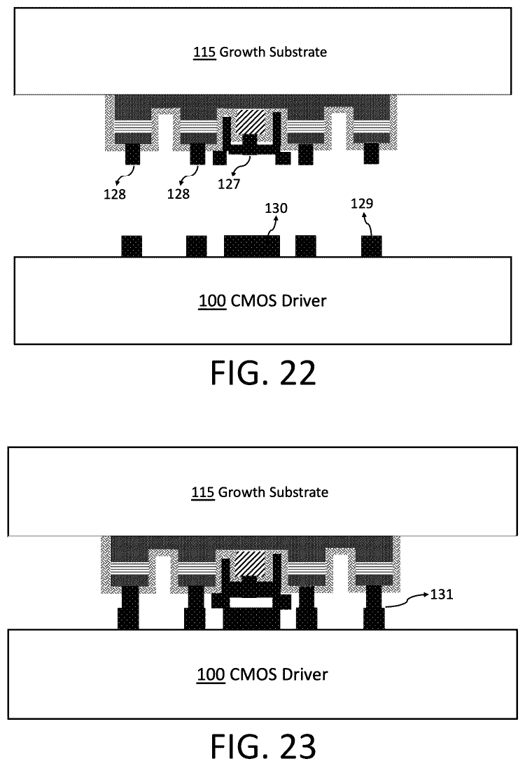

FIG. 22 illustrates the alignment process between the devices on growth substrate (115) and a CMOS driver substrate (100). The pads of light source devices (128) and (127) may be aligned to the pads (129) and (13) on the CMOS driver substrate.

FIG. 23 illustrates the bonding process between light source substrate and driver substrate when the bonding pads attach at the interface (131). Extra force and heat might be required to enhance the bonding strength.

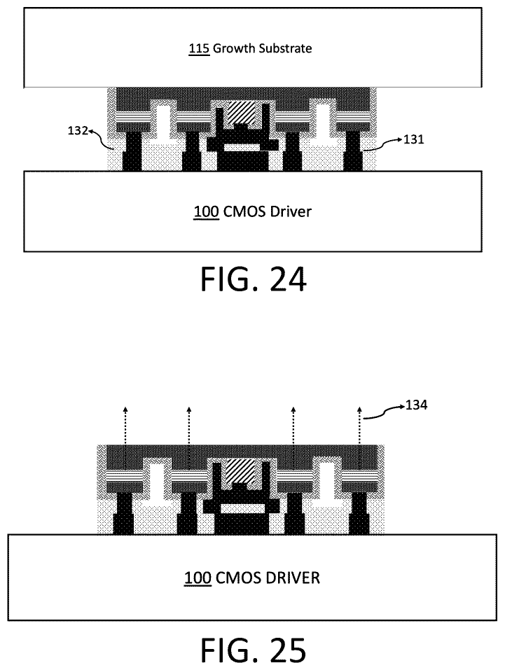

FIG. 24 illustrates the packaged light sources onto pads on a CMOS driver substrate when a hybrid bonding approach is employed. A layer (132) which might be an adhesive such a polymer or dielectric such as oxide might be used to bond the light sources to the CMOS driver (100). The interface between the pads (131) might be free from any adhesive. Extra force, heating or curing might be required to finalize the bonding process. Combination of both (132) and (131) may provide both mechanical and electrical strength required for packaging.

FIG. 25 illustrates the integrated light source onto the CMOS driver (100) when the growth substrate (115) is removed, and photons (134) are emitted from the light source backside. The light sources may be driven independently, or they can be driven together. The smaller device may leverage the lower capacitance, and they may operate faster. By having more light sources per channel a higher level of reliability may be guaranteed and if one light source gets broken the other one will continue working.

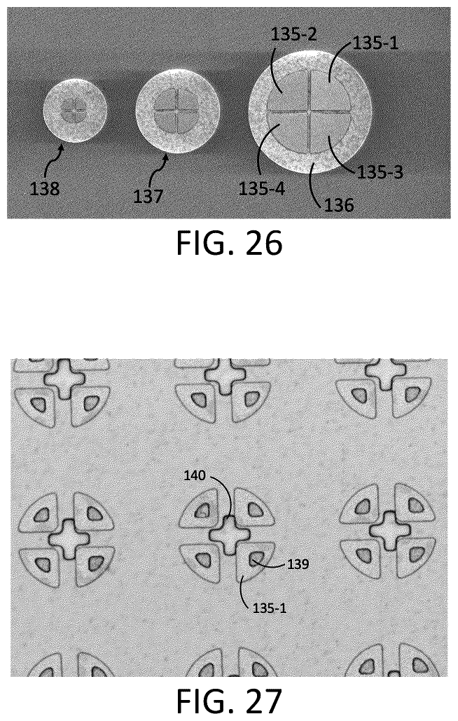

FIG. 26 illustrates the fabricated redundant micro-LEDs (137) and (138). The top contacts (135-1), (135-2), (135-3), and (135-4) are connected to individual micro-LED devices. This figure shows every micro-LED structure is divided to 4 smaller devices; however, the number of devices might be different and be defined by the system requirement.

FIG. 27 illustrates the fabricated redundant micro-LEDs in an array format when (140) defines the cathode pads and (139) is the anode pad. The area (135-1) defines the pixel area.

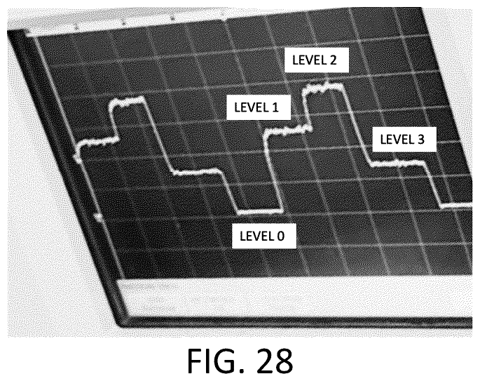

FIG. 28 illustrates the different levels of information which has been transmitted using fabricated redundant micro-LEDs. As shown in the figure, 3 levels of information, level 0, level 1, and level 2. Individual micro-LEDs could be driven separately and by controlling the intensity of the light coupled to each optical waveguide, different levels of information could be created and transmitted. This method could increase the channel's capacity without extra signal processing requirement.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Accordingly, the above description of example implementations does not define or constrain this disclosure. Other changes, substitutions, and alterations are also possible without departing from the spirit and scope of this disclosure.

1. An optical interconnect system comprising:
a primary substrate;
one or more light sources for emitting light fabricated on the primary substrate;
at least one communication medium for transmitting the light, wherein the at least one communication medium is separated from the one or more light sources by a predefined distance;
the at least one communication medium comprising a numerical aperture, and wherein the numerical aperture, the one or more light sources, and the at least one communication medium, are dimensioned to minimize loss of optical power coupling of the emitted light into the at least one communication medium; and
wherein the predefined distance is selected such that the emitted light is coupled into the at least one communication medium without an optical component.

2. The optical interconnect system of claim 1, wherein each of the light sources emit light having an identical wavelength.

3. The optical interconnect system of claim 1, wherein at least one of the light sources emit light having a different wavelength from the other light sources.

4. The optical interconnect system of claim 3, wherein the at least one of the light sources emit light comprise an emission wavelength separation selected to minimize data mixing.

5. The optical interconnect system of claim 4, further comprising a color conversion layer assembled over the one or more light sources to generate the light having different wavelengths.

6. The optical interconnect system of claim 1 wherein at least one of the light sources emit light having a different intensity from the other light sources.

7. The optical interconnect system of claim 1, wherein each of the light sources emit light having an identical intensity.

8. The optical interconnect system of claim 1, wherein a first active set of the light sources are selected to emit light while a second set of the redundant light sources is selected to emit light when the first active set of the light sources is inactive.

9. An optical interconnect system comprising:
a primary substrate;
one or more light sources for emitting light fabricated on the primary substrate;
at least one communication medium for transmitting the light, wherein the at least one communication medium is separated from the one or more light sources by a predefined distance, and wherein the at least one communication medium comprises a numerical aperture;
an optical component configured to collimate the emitted light for coupling into the at least one communication medium; and
wherein the numerical aperture, the one or more light sources, and the at least one communication medium, the predefined distance, and optical component are dimensioned to minimize loss of optical power coupling of the emitted light into the at least one communication medium.

10. The optical interconnect system of claim 9, wherein the optical component is optimized for a single wavelength or for a wide range of spectrum.

11. The optical interconnect system of claim 10, wherein a single optical component is associated with the one or more light sources.

12. The optical interconnect system of claim 11, wherein each of the one or more light sources has an individual optical component associated therewith.

13. The optical interconnect system of claim wherein the optical component is fabricated on a transparent substrate.

14. The optical interconnect system of claim 13, further comprising a waveguide to connect the one or more light sources to the transparent substrate.

15. The optical interconnect system of claim 14, wherein the waveguide comprises photo-definable polymers having a predefined refractive index suitable for light extraction, and wherein sidewalls of the waveguide comprise a reflective material to maintain the emitted light within the waveguide.

16. The optical interconnect system of claim 15, wherein the one or more light sources are fabricated or transferred on a secondary substrate, wherein the secondary substrate is connected to the primary substrate through conductive vias.

17. The optical interconnect system of claim 1, wherein the one or more light sources comprise an epitaxial structure comprising epitaxial layers having a n-type semiconductor material, a quantum well or a p-type semiconductor material, and further comprising at least one of p-doped material and n-doped material, wherein the quantum wells or quantum dots emit photons.

18. The optical interconnect system of claim 17, wherein the epitaxial layers are patterned by removing a part of the epitaxial layer using a physical or chemical processes.

19. The optical interconnect system of claim 18, wherein at least one contact is formed on top of epitaxial structure at an area thereof.

20. The optical interconnect system of claim 19, wherein a passivation layer covers a topside and sidewall of the patterned epitaxial structure, wherein the passivation layer comprises dielectrics or polymers to provide both insulating and optical properties.

21. The optical interconnect system of claim 20, wherein the passivation layer is patterned and vias are open at the area on top of the contacts and pads.

22. A method for assembling an optical interconnect system, the method comprising the steps of:
providing at least one light source for emitting light,
providing at least one communication medium for transmitting the light, wherein the at least one communication medium is separated from the one or more light sources by a predefined distance, and wherein the at least one communication medium comprises a numerical aperture;
providing an optical component configured to collimate the emitted light for coupling into the at least one communication medium; and
wherein the numerical aperture, the one or more light sources, and the at least one communication medium, the predefined distance, and optical component are dimensioned to minimize loss of optical power coupling of the emitted light into the at least one communication medium.
